(19) United States
(12) Patent Application Publication
(10) Pub. No.: US 2011/0115041 A1
(43) Pub. Date: May 19, 2011

(54) NANOWIRE CORE-SHELL LIGHT PIPES

(75) Inventors: Yaping Dan, Cambridge, MA (US); Munib Wober, Topsfield, MA (US); Kenneth B. Crozier, Cambridge, MA (US)

(73) Assignees: ZENA TECHNOLOGIES, INC., Cambridge, MA (US); PRESIDENT AND FELLOWS OF HARVARD COLLEGE, Cambridge, MA (US)

(21) Appl. No.: 12/621,497

(22) Filed: Nov. 19, 2009

(51) Int. Cl. H01L 31/0232; H01L 31/18

(52) U.S. Cl. 257/432; 438/69; 257/E31.127

(57) ABSTRACT

Embodiments relate to methods and devices comprising an optical pipe comprising a core and a cladding. An embodiment includes obtaining a substrate comprising a photodiode and a first protective layer, the first protective layer having a predetermined thickness and growing a nanowire having a length L on the photodiode, wherein the length L is greater than the predetermined thickness of the protective layer. Another embodiment includes (1) obtaining a substrate comprising a photodiode and a protective layer, (2) fabricating a nanowire light pipe on the photodiode, the light pipe comprising a nanowire core and a cladding; and (3) coating the substrate and the nanowire light pipe with a protective coating.

### RELATED APPLICATION

The present application is related to U.S. patent application Ser. No. 12/270,233, filed Nov. 13, 2008, which discloses nanowire pixels configured to collect light of different wavelengths and convert it to detectable electrical signals. The contents of U.S. patent application Ser. No. 12/270,233 are hereby incorporated by reference in its entirety.

### FIELD OF INVENTION

The embodiments relate to nanowire-core shell light pipes and manufacture thereof.

### BACKGROUND

The disclosed nanowire pixels can be fabricated in large numbers and tessellated in Cartesian or other arrangements to create an image sensor suitable for ultrahigh resolution images.

The previously disclosed nanowire pixel comprises a semiconductor nanowire which may be fabricated of silicon or other materials. The nanowire is located in a light pipe integrated on top of a conventional silicon photodiode (SiPD). The nanowire light pipe serves as a waveguide to collect and absorb light of some particular wavelengths (shorter wavelengths) and convert it into electrical signals. Other light (usually red light of longer wavelengths) that is not absorbed by the nanowire is channeled to the SiPD at the bottom of the light pipe. Conventional complementary metal oxide semiconductor (CMOS) circuitry can be used to manipulate the electrical signals from the nanowire and the SiPD that represent the light intensities of different wavelengths.

The teachings of the following references, which provide a general background in the art related to the embodiments disclosed herein, are incorporated herein by reference in their entirety: (1) Cho, Y. S., et al., 32×32 SOICMOS image sensor with pinned photodiode on handle wafer. Optical Review, 2007. 14(3): p. 125-130. Cho teaches low noise CMOS pixels. (2) Fan, H. J., P. Werner, and M. Zacharias, Semiconductor nanowires: From self-organization to patterned growth. Small, 2006. 2(6): p. 700-717. Fan teaches deposition of catalyst particles with an electron beam lithography (EBL) process and a single nanowire can be grown from the catalyst particle using the vapor-liquid-solid (VLS) process. (3) Cui, Y., et al., Diameter-controlled synthesis of single-crystal silicon nanowires. Applied Physics Letters, 2001. 78(15): p. 2214-2216. Cui teaches deposition of catalyst particles with self-assembly of prefabricated catalyst colloids. (4) Wang, Y. W., et al., Epitaxial growth of silicon nanowires using an aluminium catalyst. Nature Nanotechnology, 2006. 1(3): p. 186-189. Wang teaches synthesis of silicon nanowires at 430 C and below 400 C using aluminum catalysts. (5) Jung, Y. G., S. W. Jee, and J. H. Leea, Effect of oxide thickness on the low temperature (<=400 degrees C.) growth of cone-shaped silicon nanowires. Journal of Applied Physics, 2007. 102(4): p. 3. Jung teaches synthesis of silicon nanowires using plasma enhanced growth. (6) Kempa, T. J., et al., Single and Tandem Axial p-i-n Nanowire Photovoltaic Devices. Nano Letters, 2008. 8(10): p. 3456-3460. Kempa teaches doping the nanowire during the VLS process and a p⁺-i-n⁺ structure improves the collection efficiency of charge carriers and therefore increases the photo-voltage. (7) Cui, Y., et al., High performance silicon nanowire field effect transistors. Nano Letters, 2003. 3(2): p. 149-152. Cui teaches nanowire surface states can be minimized by surface passivation. (8) Leskela, M. and M. Ritala, Atomic layer deposition chemistry: Recent developments and future challenges. Angewandte Chemie-International Edition, 2003. 42(45): p. 5548-5554. Leskela teaches forming light pipes using the Atomic Layer Deposition (ALD) method. (9) Granqvist, C. G. and A. Hultaker. Transparent and conducting ITO films: new developments and applications. 2002: Elsevier Science Sa. Granqvist teaches indium tin oxide (ITO) is transparent to a wide range of light wavelengths. (10) Popovic, Z. D., R. A. Sprague, and G. A. N. Connell, TECHNIQUE FOR MONOLITHIC FABRICATION OF MICROLENS ARRAYS. Applied Optics, 1988. 27(7): p. 1281-1284. Popovic teaches microlens fabrication using CMOS processes. (11) Moller, S, and S. R. Forrest, Improved light out-coupling in organic light emitting diodes employing ordered microlens arrays. Journal of Applied Physics, 2002. 91(5): p. 3324-3327. Moller teaches microlens fabrication using CMOS processes.

### DESCRIPTION OF THE FIGURES

FIG. 1 is a cross sectional view illustrating a step of a method according to an embodiment. FIG. 1 shows a cross sectional view of a design for pinned silicon photodiodes prefabricated on p-Si substrate. A “window” in the SiO₂ layer is opened for the nanowire growth.

FIG. 2 is a cross sectional view illustrating a step of a method according to an embodiment. A metal catalyst nanoparticle is deposited on the p⁺ region of the photodiode

FIG. 3 is a cross sectional view illustrating a step of a method according to an embodiment. A p⁺-i-n⁺ silicon nanowire is grown vertically on p+ layer by a proper control of Vapor-Liquid-Solid (VLS) synthesis process.

FIG. 4 is a cross sectional view illustrating a step of a method according to an embodiment. A conformal coating of dielectric material is deposited by ALD.

FIG. 5 is a scanning electron microscopic photograph of silicon nanowires on a silicon wafer.

FIG. 6 is a scanning electron microscopic photograph of silicon nanowires coated with a layer of 100 nm thick Al₂O₃.

FIG. 7 is a cross sectional view illustrating a step of a method according to an embodiment. A conformal coating of a metal layer is deposited by ALD.

FIG. 8 is a cross sectional view illustrating a step of a method according to an embodiment. The metal layer is patterned for electrical isolation by photolithography or EBL processes if an array of nanowire pixels are integrated.

FIG. 9 is a cross sectional view illustrating a step of a method according to an embodiment. The surface is planarized and the light pipe top is opened for the incidence of light.

FIG. 10 is a cross sectional view illustrating a step of a method according to an embodiment. A layer of ITO is deposited and patterned on top of the device to create the electrical connection.

FIG. 11 is a cross sectional view illustrating a step of a method according to an embodiment. A microlens is fabricated on top of the light pipe to increase light collection.

### DETAILED DESCRIPTION

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented here.

The present disclosure is drawn to methods of fabricating nanowire core-shell light pipes integrated on top of photodiodes. The present disclosure is also drawn to nanowire core-shell light pipes integrated on top of photodiodes made by the disclosed methods.

In an embodiment of the invention, the first step for fabricating the nanowire pixel is to create a conventional CMOS pixel of appropriate size. Alternatively, a prefabricated conventional CMOS pixel may be obtained from a third party. In one preferred embodiment, the CMOS pixel is a “pinned” silicon photodiode. The “pinned” silicon photodiode was selected due to its low noise and the fact that its design is known to those familiar with CMOS image sensors.

An embodiment relates to a method comprising obtaining a substrate comprising a photodiode and a first protective layer, the first protective layer having a predetermined thickness and growing a nanowire having a length L on the photodiode, wherein the length L is greater than the predetermined thickness of the protective layer. One aspect further comprises etching a holes in the first protective layer to expose a surface of the photodiode and depositing a catalyst particle on the exposed surface of the photodiode. In another aspect, the catalyst comprises gold. Another aspect further comprises doping the nanowire while growing the nanowire. In another aspect, the doped nanowire has a p⁺-i-n⁺ structure.

Another aspect further comprises forming a substantially uniform dielectric cladding layer surrounding the nanowire. Another aspect further comprises comprising forming a metal layer surrounding the dielectric cladding layer. Another aspect further comprises coating the substrate and the nanowire with a second protective layer. Another aspect further comprises planarizing the second protective layer. In another aspect, the catalyst particle is removed during the planarizing. Another aspect further comprises fabricating an electrical contact to the nanowire on the planarizing layer. In another aspect, the contact comprises indium tin oxide (ITO). Another aspect further comprises comprising fabricating a microlens on top of the second protective layer.

Another embodiment relates to a method comprising obtaining a substrate comprising a photodiode and a protective layer, fabricating a nanowire light pipe on the photodiode, the light pipe comprising a nanowire core and a cladding and coating the substrate and the nanowire light pipe with a protective coating. One aspect further comprises comprising depositing a catalyst t particle on a surface of the photodiode. In another aspect, the catalyst comprises gold. Another aspect further comprises comprising doping the nanowire while growing the nanowire. In another aspect, the doped nanowire has a p⁺-i-n⁺ structure.

Another aspect further comprises forming a substantially uniform dielectric cladding layer surrounding the nanowire. Another aspect further comprises forming a metal layer surrounding the dielectric cladding layer. Another aspect further comprises coating the substrate and the nanowire with a protective layer. Another aspect further comprises planarizing the protective layer. In another aspect, the catalyst particle is removed during the planarizing. Another aspect further comprises fabricating an electrical contact to the nanowire on the planarizing layer. In another aspect, the contact comprises indium tin oxide (ITO). Another aspect further comprises fabricating a microlens on top of the second protective layer.

Another embodiment relates to a device made by any of the above methods.

In one aspect, L is in the range of 4μ to 20μ. In another aspect, the protective layer comprises, SiO₂, Si₃N₄, or a dielectric material comprising Ge. In another aspect, the cladding layer comprises, SiO₂, Si₃N₄, or a dielectric material comprising Ge. In another aspect, the cladding comprises, SiO₂, Si₃N₄, or a dielectric material comprising Ge.

FIG. 1 illustrates a cross-section of such a “pinned” photodiode which can be constructed using conventional CMOS processes. In this embodiment, the pinned photodiode is constructed on a p-type silicon wafer. In alternative embodiments, the pinned photodiode is constructed on an n-type silicon wafer. In still other alternative embodiments, the wafer may comprise germanium, silicon germanium alloys or any of the various III-V or II-VI semiconducting materials. The illustrated pinned photodiode includes p+ (heavy p doped silicon), n doped and n+ (heavily n doped silicon) regions in addition to some transistors (not shown here). Normally a protective layer deposited over the pinned photodiode to protect the structure. The protective layer may also be used as a gate oxide for a transfer or reset transistor. The protective layer typically comprises silicon oxide (SiO₂) or silicon nitride (Si₃N₄), however other materials, such as Ge based materials known in the art may be used as well. Generally, other conventional top layers, such as color filters and metal wiring layers are not used here.

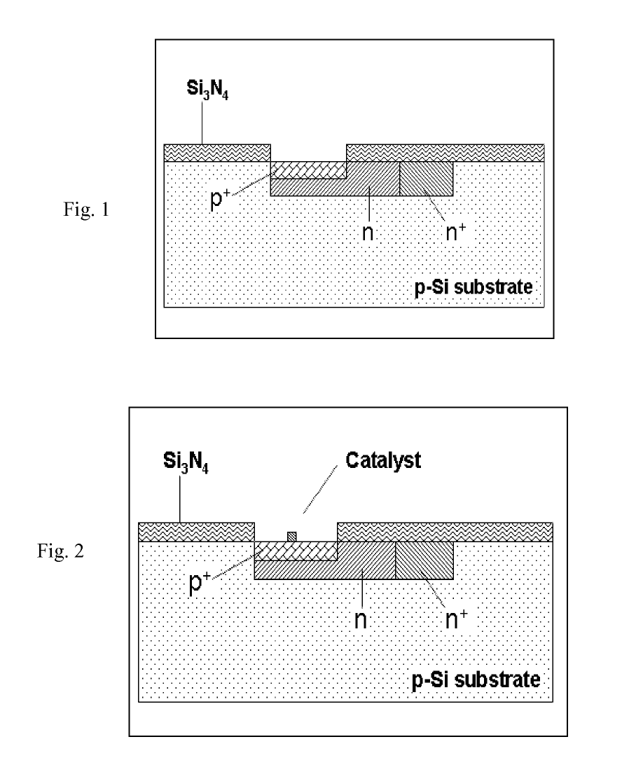

In this embodiment, this photodetector collects the light that is not absorbed by the nanowire (discuss in more detail below). For the convenience of nanowire growth, a window of micrometer size in the Si₃N₄ protective layer may be opened by photolithography (shown in FIG. 1). A catalyst particle (typically gold or gold alloy) may then be deposited on top of the p⁺ region by either a standard electron beam lithography (EBL) process or using self-assembly of prefabricated catalyst colloids, as shown in FIG. 2. Other processes for depositing catalysts, such as electroless plating may also be used.

The diameters of nanowires after growth are generally determined by the sizes of the catalyst particles. Therefore, a desired diameter of the nanowire can be synthesized by depositing a catalyst particle with an appropriate size. This step typically determines the functionality of the nanowire pixel because the nanowire diameter should be of an appropriate cross-section area to allow the transmission of light with specific wavelengths and long enough to allow the light absorption and creation of excitons (electron-hole pairs).

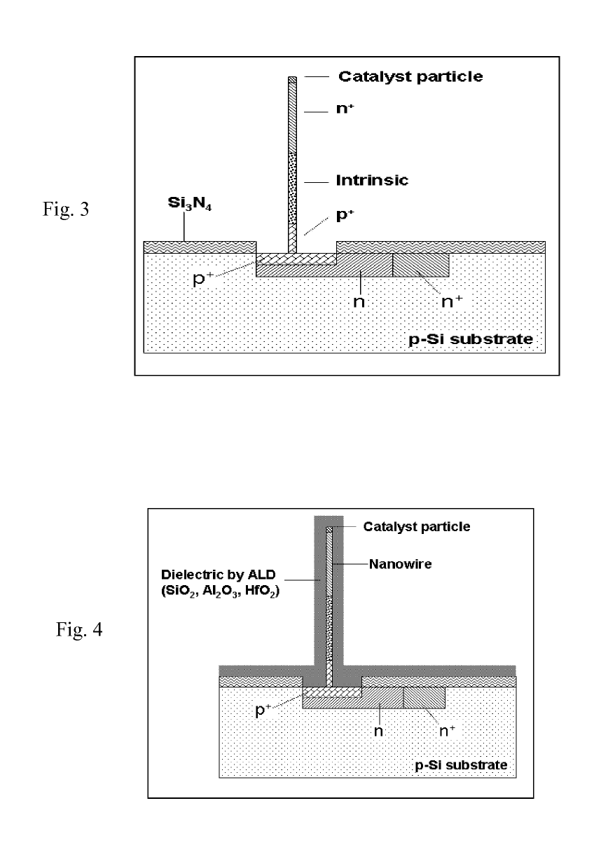

A single nanowire can be grown from the catalyst particle under proper conditions. Using silicon as an example, a suitable nanowire can be grown using the vapor-liquid-solid (VLS) process with presence of SiH₄ at, for example, 650° C. and 200 mTorr. A temperature below 450° C. is advisable for the integration compatibility of CMOS circuits and nanowire synthesis. Many researchers have been able to synthesize silicon nanowires at 430° C. or even below 400 C by using some special techniques, for example, using aluminum catalysts or plasma enhanced growth. During the VLS process, the silicon nanowire can be doped to create a p⁺-i(intrinsic)-n⁺ structure by introducing B₂H₆, H₂ and PH₃, respectively. This is shown schematically in FIG. 3.

In the illustrated embodiment, the nanowire includes n⁺, i, and p⁺ regions. Since the substrate has a p⁺ region adjacent the surface, however, the nanowire need not have a p⁺ region. That is, in another embodiment, the nanowire only includes n⁺ and i regions, the p⁺ region in the substrate completing the p-i-n structure. Additionally, as shown in FIG. 3, the nanowire is grown with a length L, where the length L is greater than the thickness of the protective layer. Typically L is in the range of 4μ to 20μ, however, shorter and longer nanowires can be grown as desired.

The p⁺-i-n⁺ structure helps to improve the performance of the nanowire pixel. When such a nanowire is reversely biased, the depletion region will extend deep into the intrinsic region where light travelling along the nanowire light pipe (discussed later) will be absorbed. The absorbed photons from the light generate electron-hole pairs. The electric field in this long depletion region helps to separate the electron-hole pairs and improves the collection efficiency of charge carriers. In this manner, the p⁺-i-n⁺ structure increases the photo-voltage.

Nanowires have a higher surface-to-volume ratio than the corresponding bulk materials. Therefore the surface states of nanowires play a more important role in their electronic and optical properties. The impact of nanowire surface states, however, can be minimized by surface passivation after the nanowire synthesis illustrated in FIG. 3. Typically, surface passivation can be achieved with a monolayer of materials to react with silicon dangling bonds at the surface of the nanowire. This is accomplished with the formation of stable bonds after reaction. Advantageously, passivation has almost no effect on the nanowire physical dimension since it is only one-monolayer thick.

FIG. 4 illustrates the formation of the light pipe structure. A conformal coating of dielectric material such as SiO₂, HfO₂ or Al₂O₃, with a thickness of sub-micrometer to few micrometers may be deposited on the nanowire. In one embodiment, the conformal coating is deposited using the Atomic Layer Deposition (ALD) method which has an atomic resolution. Other deposition methods known in the art may also be used.

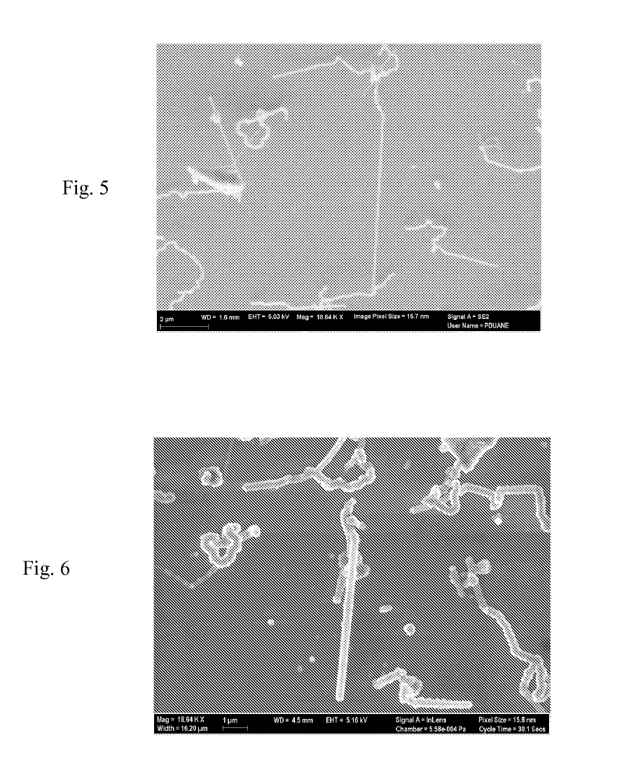

FIGS. 5 and 6 show the results of experimentally coated the silicon nanowires. The uncoated nanowires illustrated in FIG. 5 have diameters of approximately 100 nm. These nanowires were coated with a 100 nm thick Al₂O₃ layer using ALD (illustrated in FIG. 6). The ALD deposited Al₂O₃ has uniformly coated the nanowires and enlarged them from approximately 100 nm to approximately 200 nm.

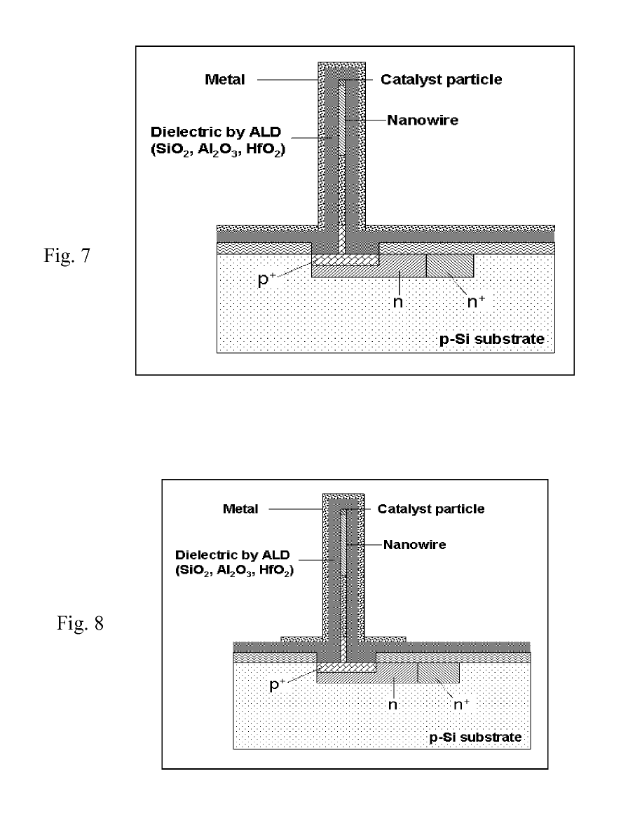

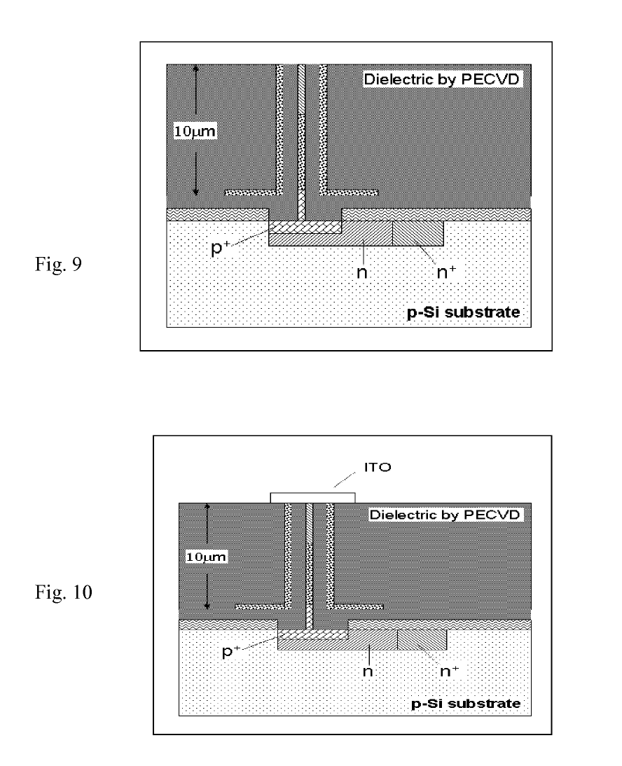

FIG. 7 illustrates another step in the process. A layer of metal (e.g. platinum) with a thickness of approximately 100 nm may be deposited on top of the dielectric layer. Deposition may be accomplished with ALD, for example. The dielectric cladding layer defines the radial dimension of the light pipe. Further, the dielectric cladding layer allows incident light of particular wavelengths to be confined within the nanowire. The metal layer also helps to confine light and reduce optical cross-talking in addition to providing electrical contact to the nanowire at its top (see FIGS. 9 and 10). Crosstalk is a phenomenon by which a signal transmitted in one pixel or channel of a transmission system creates an undesired effect in another pixel or channel. For optical sensors, there are at least three types of crosstalk: (1) spatial optical crosstalk, (2) spectral crosstalk, and (3) electrical crosstalk. Spatial optical crosstalk occurs when the pixel size approaches the wavelength of visible light. Diffraction causes a sharp increase in the amount of light that reaches adjacent photodiodes rather than the desired photodiode. Spectral crosstalk is when light that should have been blocked by a color filter manages to pass through the filter. Electrical crosstalk is when photo-generated electrons travel to adjacent pixels through the silicon substrate. If an array of nanowire image sensors is integrated on chip, non-contact photolithography or electron beam lithography may be used to pattern the metal layer to electrical isolate individual devices from each other (FIG. 7).

FIG. 9 illustrates the next step in the method according to this embodiment. In this step, the overall structure is coated with a protective layer, such as SiO₂. Deposition may be accomplished, for example by a Plasma Enhanced Chemical Vapor Deposition (PECVD) process. In this embodiment, this step is followed by a chemical polishing process to planarize the surface and reduce the thickness (FIG. 10). During this process, the catalyst particle is preferably removed and the top of the light pipe is opened for the incidence of light.

To complete an electrical contact between the nanowire and the metallic layer, a thin layer of a conductive material may deposited on the top of structure. Preferably the conductive material is transparent to light. One suitable highly conductive transparent material is Indium Tin Oxide (ITO). Other transparent conductive materials may also be used. If ITO is used, an optional adhesion layer or buffer layer may be deposited before the ITO to improve adhesion of the ITO to the dielectric layer. Example adhesion layer materials include, but are not limited to Cr and Ti. Typically, the adhesion layer half a nanometer thick or thinner to minimize the effects of the adhesion layer on light propagation. The conductive materials may be deposited by sputtering and then patterned by photolithography and etching process (see FIG. 8). Other deposition and patterning processes known in the art may also be used. Since ITO is transparent to a wide range of light wavelengths, the incidence of light into the pipe will not be affected by the ITO layer.

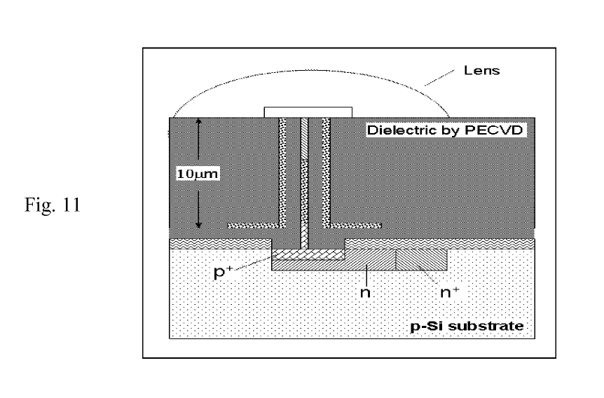

FIG. 11 illustrates another step that may be performed. In this step, a microlens is fabricated on top of the light pipe to increase the efficiency of light collection. Microlens fabrication is a knows process used in commercial CMOS image sensors.

The foregoing description of the invention has been presented for purposes of illustration and description. It is not intended to be exhaustive or to limit the invention to the precise form disclosed, and modifications and variations are possible in light of the above teachings or may be acquired from practice of the invention. The drawings and description were chosen in order to explain the principles of the invention and its practical application. It is intended that the scope of the invention be defined by the claims appended hereto, and their equivalents.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

The complete teachings of all references cited herein are incorporated herein by reference in entirety. While various aspects and embodiments have been disclosed herein, other aspects and embodiments will be apparent to those skilled in the art. The various aspects and embodiments disclosed herein are for purposes of illustration and are not intended to be limiting, with the true scope and spirit being indicated by the following claims.

We claim:

1. A method comprising:
obtaining a substrate comprising a photodiode and a first protective layer, the first protective layer having a predetermined thickness; and
growing a nanowire having a length L on the photodiode,
wherein the length L is greater than the predetermined thickness of the protective layer.

2. The method of claim 1, further comprising etching a holes in the first protective layer to expose a surface of the photodiode and depositing a catalyst particle on the exposed surface of the photodiode.

3. The method of claim 2, wherein the catalyst comprises gold.

4. The method of claim 1, further comprising doping the nanowire while growing the nanowire.

5. The method of claim 4, wherein the doped nanowire has a p⁺-i-n⁺ structure.

6. The method of claim 5, further comprising forming a substantially uniform dielectric cladding layer surrounding the nanowire.

7. The method of claim 6, further comprising forming a metal layer surrounding the dielectric cladding layer.

8. The method of claim 7, further comprising coating the substrate and the nanowire with a second protective layer.

9. The method of claim 8, further comprising planarizing the second protective layer.

10. The method of claim 9, wherein the catalyst particle is removed during the planarizing.

11. The method of claim 9, further comprising fabricating an electrical contact to the nanowire on the planarizing layer.

12. The method of claim 11, herein the contact comprises indium tin oxide (ITO).

13. The method of claim 11, further comprising fabricating a microlens on top of the second protective layer.

14. A device made by the method of claim 1.

15. A method comprising:
obtaining a substrate comprising a photodiode and a protective layer;
fabricating a nanowire light pipe on the photodiode, the light pipe comprising a nanowire core and a cladding; and
coating the substrate and the nanowire light pipe with a protective coating.

16. The method of claim 15, further comprising depositing a catalyst t particle on a surface of the photodiode.

17. The method of claim 16, wherein the catalyst comprises gold.

18. The method of claim 15, further comprising doping the nanowire while growing the nanowire.

19. The method of claim 18, wherein the doped nanowire has a p⁺-i-n⁺ structure.

20. The method of claim 19, further comprising forming a substantially uniform dielectric cladding layer surrounding the nanowire.

21. The method of claim 20, further comprising forming a metal layer surrounding the dielectric cladding layer.

22. The method of claim 21, further comprising coating the substrate and the nanowire with a protective layer.

23. The method of claim 22, further comprising planarizing the protective layer.

24. The method of claim 23, wherein the catalyst particle is removed during the planarizing.

25. The method of claim 24, further comprising fabricating an electrical contact to the nanowire on the planarizing layer.

26. The method of claim 25, wherein the contact comprises indium tin oxide (ITO).

27. The method of claim 25, further comprising fabricating a microlens on top of the second protective layer.

28. A device made by the method of claim 27.

29. The method of claim 1, wherein L is in the range of 4μ to 20μ.

30. The method of claim 1, wherein the protective layer comprises, SiO₂, Si₃N₄, or a dielectric material comprising Ge.

31. The method of claim 6, wherein the cladding layer comprises, SiO₂, Si₃N₄, or a dielectric material comprising Ge.

32. The method of claim 15, wherein the cladding comprises, SiO₂, Si₃N₄, or a dielectric material comprising Ge.
